(19) United States
(12) Patent Application Publication
(10) Pub. No.: US 2025/0283820 A1
(43) Pub. Date: Sep. 11, 2025

(54) SILICON-ON-INSULATOR (SOI) CARRIER CHIP AND METHODS OF MANUFACTURE THEREOF

(71) Applicant: Teracyte Analytics Ltd., Yokneam (IL)

(72) Inventors: Shay KAPLAN, Givat Elah (IL); Yoav NISSAN-COHEN, Mishmar David (IL)

(73) Assignee: Teracyte Analytics Ltd., Yokneam (IL)

(21) Appl. No.: 19/219,160

(22) Filed: May 27, 2025

Related U.S. Application Data
(63) Continuation of application No. PCT/IB2023/061935, filed on Nov. 27, 2023.
(60) Provisional application No. 63/428,070, filed on Nov. 27, 2022.

(51) Int. Cl. G01N 21/64; G01N 21/03; H01L 21/762

(52) U.S. Cl. CPC G01N 21/6452; G01N 21/03; H01L 21/76243; G01N 2021/0346; G01N 2021/6482

(57) ABSTRACT

A carrier chip that includes a plurality of wells is formed on a silicon-on-insulator (SOI) wafer. The carrier chip is designed to capture biological cells is its wells. The SOI wafer includes a top silicon layer, a bottom oxide (BOX) layer, and a silicon substrate. The optical reflective characteristics of the top silicon layer and the substrate are substantially similar. By performing an etch, using the BOX layer as an etch stop, well-defined wells depths are formed through the top silicon layer. Once the BOX layer is etched from the bottom of each well, the bottom of the well and the surface of the top silicon layer has substantially similar optical reflective characteristics that improve image contrast when images are taken of the carrier chip.

### CROSS-REFERENCE TO RELATED APPLICATIONS

This application is a continuation of International Application No. PCT/IB2023/061935 filed on Nov. 28, 2023, now pending, which claims the benefit of U.S. Provisional Application No. 63/428,070 filed Nov. 27, 2022, the contents of which are hereby incorporated by reference.

### TECHNICAL FIELD

The present disclosure relates generally to carrier chips used in fluorescence imaging of cells and more specifically to a silicon-on-insulator carrier chip.

### BACKGROUND

Fluorescence imaging is commonly used for non-invasively imaging various biological cells. This allows research on biological processes of, for example, living cells, or other like biological matter. The commercial ways available to image live cells are by using live-cell imagers and certain disposables that allow the capture and maintenance of such cells. The live-cell imaging performs time-lapse microscopy of living cells that are observed over time, for example, by capturing images of the live cells. There are several types of microscopies used for live-cell imaging which include, phase contrast, quantitative phase contrast, fluorescent, and holotomography. In some cases, a chip having a plurality of wells to place the live cells therein is used for the performance of such microscopy.

An example of a portion of a chip 100 having wells 110 therein is shown in FIG. 1. Wells 110 are depressions within the silicon substrate (also referred to herein as substrate) of the chip and are organized in rows and columns. For example, a well 110-i-j, where each of ‘i’ and ‘j’ are integers equal to or greater than ‘1’, is position in row ‘i’ and in column ‘j’. For example, but not by way of limitation, a multiwell chip having 250,000 wells may be organized 500-by-500 with 1≤i,j≤500. The same multiwell chip may be arranged differently as 1000-by-250 with 1≤i≤1000 and 1≤j≤250 (or vice versa, for that matter). Each such chip is operative individually and used by certain microscopy equipment for performing fluorescence imaging. In some cases, bright-field microscopy is used where the specimen is illuminated with a white light source, and the image is formed by the light that is transmitted through the specimen and reflected back from the well's bottom surface. In some cases, a plurality of such chips is mounted on a holder that is manipulated under the view of the microscope and images are taken thereof.

Most cell arrays are inspected using inverted microscopes, and therefore are made on transparent substrates. However, there are some advantages for using opaque well arrays with upright microscopes such as, reducing cross talk between fluorescence signals from adjacent cell. It has been identified that the surface quality of the well bottom has a major impact on the performance of the array to increase optical signals in cell imaging.

It would therefore be advantageous to provide a solution that would overcome the challenges noted above.

### SUMMARY

A summary of several example embodiments of the disclosure follows. This summary is provided for the convenience of the reader to provide a basic understanding of such embodiments and does not wholly define the breadth of the disclosure. This summary is not an extensive overview of all contemplated embodiments and is intended to neither identify key or critical elements of all embodiments nor to delineate the scope of any or all aspects. Its sole purpose is to present some concepts of one or more embodiments in a simplified form as a prelude to the more detailed description that is presented later. For convenience, the term “certain embodiments” may be used herein to refer to a single embodiment or multiple embodiments of the disclosure.

Some example embodiments disclosed herein include a carrier chip for capturing biological cells. The carrier chip comprises: a silicon-on-insulator (SOI) structure, wherein the SOI structure comprises: a top silicon layer; a bottom oxide (BOX) layer; a silicon substrate; and a plurality of wells, wherein each well of the plurality of wells is partially disposed in the top silicon layer and partially disposed in the BOX layer, wherein a bottom surface of each well of the plurality of wells has an optical reflective characteristic of a top silicon layer surface.

Some example embodiments disclosed herein also include method for manufacturing a carrier chip for capturing cells. The method comprises: manufacturing a silicon-on-insulator (SOI) structure that comprises a top silicon layer, a bottom oxide (BOX) layer, and a silicon substrate; performing a lithography definition of a plurality of wells, wherein each well of the plurality of wells is designed to capture at least a cell therein; etching the top silicon layer to create the plurality of wells; stripping an etch mask; and etching the BOX layer at a bottom of each well of the plurality of wells, wherein the each well of the plurality of wells is partially disposed in the top silicon layer and partially disposed in the BOX layer, and wherein a bottom surface of each well of the plurality of wells has an optical reflective characteristic of a top silicon layer surface.

Some example embodiments disclosed herein also include method for manufacturing a carrier chip for capturing cells. The method comprises: performing a lithography definition on a semiconductor structure of a plurality of wells, wherein each well of the plurality of wells is designed to capture at least a cell therein; etching a top silicon layer to create the plurality of wells; stripping an etch mask; and etching a bottom oxide (BOX) layer at a bottom surface of each well of the plurality of wells, wherein the semiconductor structure is a silicon-on-insulator (SOI) structure that comprises the top silicon layer, the BOX layer and a silicon substrate, wherein the each well of the plurality of wells is partially disposed in the top silicon layer and partially disclosed in the BOX layer, and wherein the bottom surface of the each well of the plurality of wells has substantially similar optical reflective characteristics of the top silicon layer.

### BRIEF DESCRIPTION OF THE DRAWINGS

The subject matter disclosed herein is particularly pointed out and distinctly claimed in the claims at the conclusion of the specification. The foregoing and other objects, features, and advantages of the disclosed embodiments will be apparent from the following detailed description taken in conjunction with the accompanying drawings.

FIG. 1 an illustration of a portion of a carrier chip having wells therein.

FIG. 2 is an illustration of a cross-section of a silicon on insulator (SOI) wafer prior to use according to an embodiment.

FIG. 3 is an illustration of a cross-section of a silicon on insulator (SOI) wafer after etching wells therein according to an embodiment.

FIG. 4 is an illustration of a cross-section of a silicon on insulator (SOI) wafer after etching wells therein and adding a cell-capturing coating at the bottom of the wells according to an embodiment.

FIG. 5 is an illustration of a cross-section of a silicon on insulator (SOI) wafer after etching wells therein including a bottom oxide (BOX) controlled undercutting according to an embodiment.

FIG. 6 is a manufacturing flow of manufacturing steps of a carrier chip according to a first embodiment.

FIG. 7 is a manufacturing flow of manufacturing steps of a carrier chip according to a second embodiment.

### DETAILED DESCRIPTION

It is important to note that the embodiments disclosed herein are only examples of the many advantageous uses of the innovative teachings herein. In general, statements made in the specification of the present application do not necessarily limit any of the various claimed embodiments. Moreover, some statements may apply to some inventive features but not to others. In general, unless otherwise indicated, singular elements may be in plural and vice versa with no loss of generality. In the drawings, like numerals refer to like parts through several views.

A carrier chip comprising a plurality of wells is formed on a silicon-on-insulator (SOI) semiconductor wafer. The carrier chip is designed to capture in its wells' biological cells. The SOI wafer comprises a top single crystal silicon layer, which may alternatively be an epi silicon layer or polysilicon layer, a bottom oxide (BOX) layer, and a silicon substrate. The optical reflection characteristics of the top silicon layer surface and the substrate surface are substantially similar. By performing an etch, using the BOX layer as an etch stop, well-defined well depths are formed through the top silicon layer. Once the BOX layer is etched from the bottom of each well, the bottom of the well and the surface of the top silicon layer present substantially similar optical reflective characteristics that improve image contrast when images are taken of the carrier chip. The improvement in image contrast enables enhanced distinction between, for example, well perimeters and a cell perimeter for cells captured in the plurality of wells.

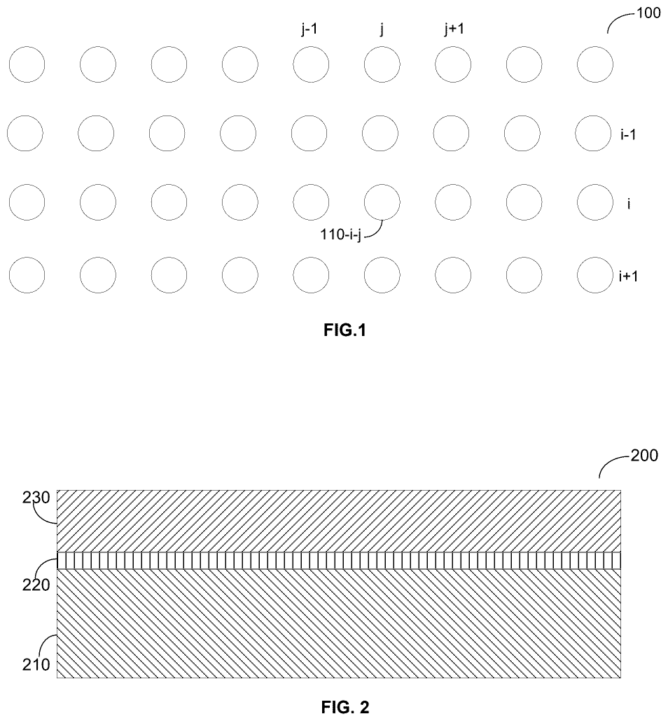

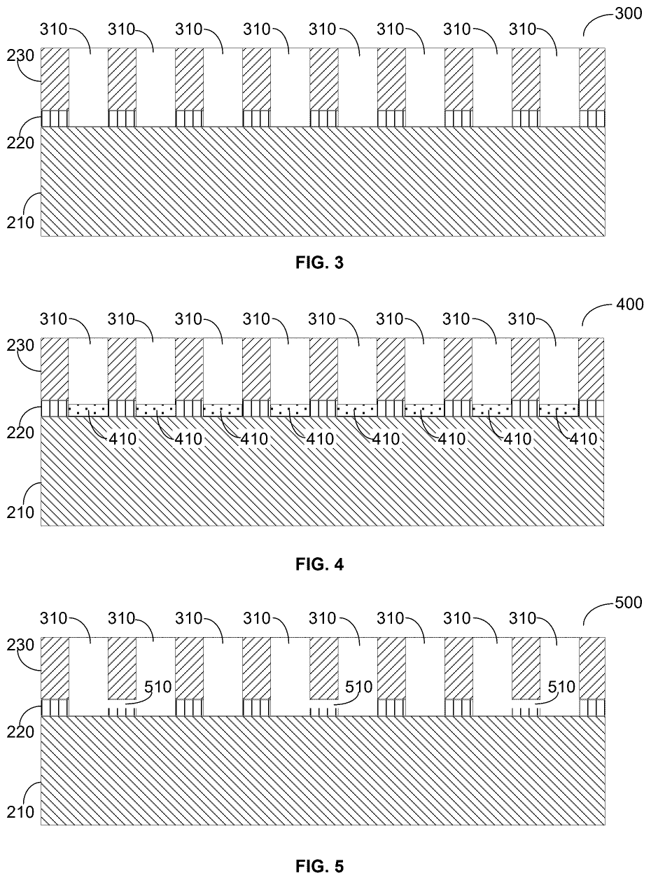

Reference is now made to FIG. 2 that depicts an example illustration of a cross-section of a silicon-on-insulator (SOI) wafer 200 prior to use according to an embodiment. The SOI wafer 200 includes three layers. A substrate layer 210, made of silicon, which provides for the physical integrity of the structure. A bottom oxide (BOX) layer 220, which forms an insulator between the substrate 210 and a top silicon layer 230, which is typically used to form electronic devices thereon or therein. Therefore, such top silicon layer 230 may also be referred to and used as a device layer. In an embodiment, the top silicon layer 230 is made of poly silicon or Epi-poly Silicon. The structure shown in FIG. 2 provides the basis for the embodiments discussed herein.

FIG. 3 is an example illustration of a cross-section 300 of an SOI wafer after etching wells therein according to an embodiment. Initially, and as further explained herein, the wells are formed within the top silicon layer 230 using etch techniques that typically stop at the BOX layer 220. The forming of wells (or cavities) within the top silicon layer 230 involves an initial etching of the silicon layer 230 up to the BOX layer 220 but that does not completely etch the BOX layer 220. The well-defined wells (or cavities) that are formed are disposed about the top silicon layer 230. Subsequent to that, the BOX layer in each well may be further etched as explained herein, forming the plurality of wells 310. The subsequent etching of the BOX layer 220 etches the BOX layer that is exposed within the wells formed through the initial etching of the top silicon layer 230. The wells 310 extend from the surface of the top silicon layer 230 all the way to the top of the substrate 210. The well 310 is a cavity that penetrates through the top silicon layer 230 and the BOX layer 220 and thus, partially disposed in the top silicon layer 230 and partially disposed in the BOX layer 220.

As an example, the well 310 may be a hollow space that is surrounded by the top silicon layer 230 and the BOX layer 220. In a further example, the side wall of the well 320 may include the top silicon layer 230 and the BOX layer 220, and the bottom surface of the well 320 may be the substrate 210. The advantage that is provided by such structure for a carrier chip is that the optical reflection characteristics of the top silicon layer 230 and a surface of the bottom of the wells 310 have substantially similar optical reflective characteristics. To this end, the image processing performed by dedicated imaging devices is improved in accuracy, as better differentiation between a cell trapped in a well and its surroundings is achieved. An improved image contrast between the well perimeter and the cell perimeter is obtained for distinction.

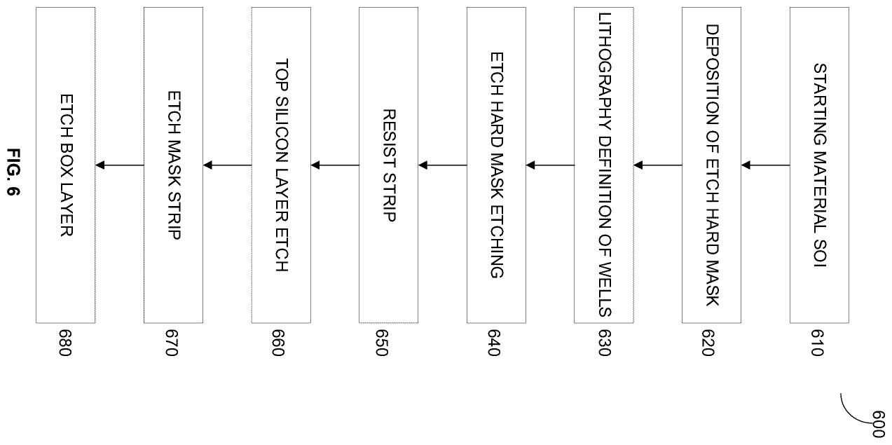

FIG. 4 is an example illustration of a cross-section 400 of an SOI wafer after etching wells therein and adding a cell-capturing coating at the bottom of the wells according to an embodiment. In addition to that which has been already described in FIG. 3, and not repeated here for sake of being concise, an additional coating layer 410 is added at the bottom of each well of the wells 310. The coating layer 410 is an adhesion layer that is designed to improve the adhesion of the captured cells to the well. The coating layer 410 may be removed only from the surface of the top silicon layer 230, while leaving the coating layer 410 laying on the well 310 bottom surface. For example, the adhesion layer may be deposited on both the surface of the top silicon layer 230 and the bottom surface of the well 310 during the lithography and etch process. However, the lithography and etch process described herein removes the adhesion layer on the surface of the top silicon layer 230 to result the adhesion layer only at the bottom surface of the well 310 as the coating layer 410 for capturing cells. The configuration described herein allows effective adhesion and capturing of cells within the wells 310 and not on the surface of the top silicon layer 230.

FIG. 5 is an example illustration of a cross-section 500 of a SOI wafer after etching wells therein including BOX controlled undercutting according to an embodiment. Accordingly, the BOX layer 220 etch may be extended so as to undercut the device layer and create connecting channels 510 between wells 310. This allows for chemical and/or ion communication between cells in adjacent wells 310. The process needs to be well controlled to avoid total etching of the BOX layer 220 and delaminating of the device layer (or top silicon layer 230).

In an embodiment, an etch of the top silicon layer 230 uses a Si reactive ion etch process, or a deep reactive ion process, following lithography and etch mask definition steps to achieve the desired well wall angle. It should be noted that the processes of lithography for etch mask definition, the etch mask type, the process sequences are all as used in microelectronic manufacturing, and the actual choice of process and processing sequence is versatile and may be selected based on, for example, economics and availabilities of manufacturing site tool and expertise. Such versatility of the disclosed embodiments with respect to, for example, but not limited to, etch mask definition, etch mask type, and the like, are advantageous and thus, the process may be utilized in various settings and conditions.

FIG. 6 is an example manufacturing flow 600 of manufacturing steps of a carrier chip according to a first embodiment. In this case a hard mask option is shown. It should be understood from the on-set that standard process steps are omitted from the following description (e.g., cleaning, dicing, etc.) for the purpose of conciseness of the description herein, and not materially contributing to the clarity of implementation of the disclosed embodiments. One of ordinary skill in the art would understand that standard lithography steps that are not explicitly described herein may be conducted in between the manufacturing steps described herein. Furthermore, as may be appropriate, a specific step described herein may be performed earlier or later in the process.

At 610, a starting material is provided, for example, an SOI wafer.

At 620, a deposition of an etch hard mask takes place which provides the locations of the wells on the SOI wafer, for example, wells 310.

At 630, lithography definition of the wells, for example wells 310, is performed.

At 640, etching of the hard mask is performed.

At 650, a resist strip process is performed. In an embodiment, step 650 may be performed after step 660.

At 660, a top silicon layer etch is performed, for example etching of the top silicon layer 230.

At 670, a strip of the hard mask is performed. In an embodiment, step 670 may be performed after step 680.

At 680, a BOX layer etch is performed, for example etching of the BOX layer 220. As noted, in an embodiment, an etch extension may take place to extend channels, for example channels 510, between adjacent wells.

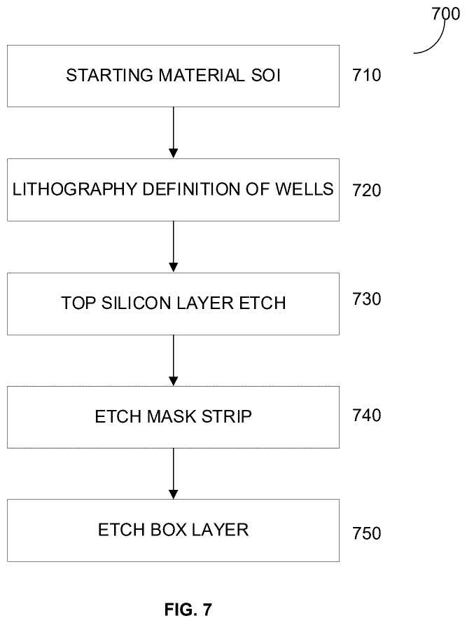

FIG. 7 is an example manufacturing flow 700 of manufacturing steps of a carrier chip according to a second embodiment. In this case a resist mask option is shown. It should be understood from the on-set that standard process steps are omitted from the following description (e.g., cleaning, dicing, etc.) for the purpose of conciseness of the description herein, and not materially contributing to the clarity of implementation of the disclosed embodiments. One of ordinary skill in the art would understand that standard lithography steps that are not explicitly described herein may be conducted in between the manufacturing steps described herein. Furthermore, as may be appropriate, a specific step described herein may be performed earlier or later in the process.

At 710, a starting material is provided, for example, an SOI wafer.

At 720, lithography definition of the wells, for example wells 310, is performed.

At 730, a top silicon layer etch is performed, for example etching of the top silicon layer 230.

At 740, an etch of the mask is performed. In an embodiment, S740 may be performed after S750.

At 750, a BOX layer etch is performed, for example etching (or stripping) of BOX layer 220. As noted, in an embodiment, an etch extension may take place to extend channels, for example channels 510, between adjacent wells.

In an embodiment, shallow marks (e.g., for focus, navigation, etc.) are etched into the top of the top silicon layer. Such etching may be performed before etching of the wells using a lithography and etch steps.

It should be noted that the wells are shown as circular tubes penetrating into the surface of the SOI merely for illustrative purpose and should not be viewed as limited by such a circular view. Other embodiments are possible without departing from the scope of the disclosed embodiments. For example, and without limitation, the well (thus, the well circumference), from a top view, may be any kind of polygon including a triangle, a square, a hexagon, and so on.

It should be further understood that the figures showing various cross-sections, and in particular FIGS. 2-4, are not meant to be to scale, and rather are drawn so as to clearly present various aspects of the embodiments discussed herein. In the case of polygonal wells, wet non-isotropic etch process may be used when the top silicon layer 230 is a single crystal <100> Si material. In this case, wall angles will have angles that conform with the crystal plane indices. The wet etch may include etching with, for example, hot potassium hydroxide (KOH) solution, tetramethylammonium hydroxide (TMAH) solution, or the like solutions as known in the art. These wet etches are performed using hard etch masks that are silicon nitride (SiN) or silicon dioxide (SiO₂) based.

In another embodiment, a transparent substrate may be used for the substrate 210 in lieu of silicon. The substrate 210 starting material may be a transparent material, on top of which the BOX layer 220 and the top silicon layer 230 are present. In an embodiment, glass (e.g., borosilicate glass, or the like) or fused silica may be used as the substrate 210, which may further eliminate the need for the BOX layer 220. In an embodiment, where both reflective surfaces are required, or the substrate is optically transparent, a deposition of a thin layer of Titanium, amorphous Silicon, or a reflective material which is process compatible and bio compatible, may be performed, thus providing the sufficient quality of reflectivity.

All examples and conditional language recited herein are intended for pedagogical purposes to aid the reader in understanding the principles of the disclosed embodiment and the concepts contributed by the inventor to furthering the art and are to be construed as being without limitation to such specifically recited examples and conditions. Moreover, all statements herein reciting principles, aspects, and embodiments of the disclosed embodiments, as well as specific examples thereof, are intended to encompass both structural and functional equivalents thereof. Additionally, it is intended that such equivalents include both currently known equivalents as well as equivalents developed in the future, i.e., any elements developed that perform the same function, regardless of structure.

It should be understood that any reference to an element herein using a designation such as “first,” “second,” and so forth does not generally limit the quantity or order of those elements. Rather, these designations are generally used herein as a convenient method of distinguishing between two or more elements or instances of an element. Thus, a reference to first and second elements does not mean that only two elements may be employed there or that the first element must precede the second element in some manner. Also, unless stated otherwise, a set of elements comprises one or more elements.

As used herein, the phrase “at least one of” followed by a listing of items means that any of the listed items can be utilized individually, or any combination of two or more of the listed items can be utilized. For example, if a system is described as including “at least one of A, B, and C,” the system can include A alone; B alone; C alone; 2A; 2B; 2C; 3A; A and B in combination; B and C in combination; A and C in combination; A, B, and C in combination; 2A and C in combination; A, 3B, and 2C in combination; and the like.

What is claimed is:

1. A carrier chip for capturing biological cells, comprising:
a silicon-on-insulator (SOI) structure, wherein the SOI structure comprises:
a top silicon layer;
a bottom oxide (BOX) layer;
a silicon substrate; and
a plurality of wells, wherein each well of the plurality of wells is partially disposed in the top silicon layer and partially disposed in the BOX layer, wherein a bottom surface of each well of the plurality of wells has an optical reflective characteristic of a top silicon layer surface.

2. The carrier chip of claim 1, wherein the top silicon layer surface and a silicon substrate surface have substantially similar optical reflective characteristics.

3. The carrier chip of claim 2, wherein the substantially similar optical reflective characteristics of the top silicon layer surface and the bottom surface of each well of the plurality of wells are designed to provide an image contrast between a well perimeter and a cell perimeter therein for the plurality of wells.

4. The carrier chip of claim 1, further comprising:
a channel connecting a first well of the plurality of wells and a second well of the plurality of wells, wherein the first well and the second well are adjacently positioned.

5. The carrier chip of claim 4, wherein the channel is designed for chemical communication between at least a first cell in the first well and a second cell in the second well.

6. The carrier chip of claim 4, wherein the channel is designed for ion communication between at least a first cell in the first well and a second cell in the second well.

7. The carrier chip of claim 1, wherein a well circumference is any one of: a circle and a polygon.

8. The carrier chip of claim 1, further comprising:
an adhesion layer at the bottom surface of each well of the plurality of wells.

9. The carrier chip of claim 1, wherein the top silicon layer is any one of: epi silicon and polysilicon.

10. A method for manufacturing a carrier chip for capturing cells, the method comprising:
manufacturing a silicon-on-insulator (SOI) structure that comprises a top silicon layer, a bottom oxide (BOX) layer, and a silicon substrate;
performing a lithography definition of a plurality of wells, wherein each well of the plurality of wells is designed to capture at least a cell therein;
etching the top silicon layer to create the plurality of wells;
stripping an etch mask; and
etching the BOX layer at a bottom of each well of the plurality of wells, wherein the each well of the plurality of wells is partially disposed in the top silicon layer and partially disposed in the BOX layer, and
wherein a bottom surface of each well of the plurality of wells has an optical reflective characteristic of a top silicon layer surface.

11. The method of claim 10, wherein the top silicon layer surface and a silicon substrate surface have substantially similar optical reflective characteristics.

12. The method of claim 11, wherein the substantially similar optical reflective characteristics of the top silicon layer surface and the bottom surface of each well of the plurality of wells are designed to provide an image contrast between a well perimeter and a cell perimeter for the plurality of wells.

13. The method of claim 10, further comprises:
depositing an etch hard mask, wherein the lithography definition is performed on the SOI structure with the etch hard mask.

14. The method of claim 10, wherein subsequent to performing the lithography definition and prior to etching the top silicon layer the method further comprises:
etching an etch hard mask; and
performing a resist strip.

15. The method of claim 10, wherein etching the BOX layer further comprises:
etching a channel connecting a first well of the plurality of wells and a second well of the plurality of wells.

16. The method of claim 15, wherein the channel is designed for chemical communication between at least a first cell in the first well and a second cell in the second well.

17. The method of claim 15, wherein the channel is designed for ion communication between at least a first cell in the first well and a second cell in the second well.

18. The method of claim 10, wherein a well circumference is any one of: a circle and a polygon.

19. The method of claim 10, further comprising:
depositing an adhesion layer on the bottom surface of each well of the plurality of wells.

20. The method of claim 10, wherein the top silicon layer is one any of: epi silicon and polysilicon.

21. A method for manufacturing a carrier chip for capturing cells, the method comprising:
performing a lithography definition on a semiconductor structure of a plurality of wells, wherein each well of the plurality of wells is designed to capture at least a cell therein;
etching a top silicon layer to create the plurality of wells;
stripping an etch mask; and
etching a bottom oxide (BOX) layer at a bottom surface of each well of the plurality of wells,
wherein the semiconductor structure is a silicon-on-insulator (SOI) structure that comprises the top silicon layer, the BOX layer and a silicon substrate,
wherein the each well of the plurality of wells is partially disposed in the top silicon layer and partially disclosed in the BOX layer, and
wherein the bottom surface of the each well of the plurality of wells has substantially similar optical reflective characteristics of the top silicon layer.

22. The method of claim 21, wherein the top silicon layer and the silicon substrate have the substantially similar optical reflective characteristics.

23. The method of claim 22, wherein the substantially similar optical reflective characteristics of the top silicon layer and the bottom surface of each well of the plurality of wells are designed to provide an image contrast that enables identification of each of a well perimeter and cell perimeter.

24. The method of claim 22, wherein prior to performing the lithography definition the method further comprises:
depositing an etch hard mask.

25. The method of claim 22, wherein subsequent to performing the lithography definition and prior to etching the top silicon layer the method further comprises:
etching an etch hard mask; and
performing a resist strip.

26. The method of claim 22, wherein etching the BOX layer further comprises:
etching a channel connecting a first well of the plurality of wells and a second well of the plurality of wells.

27. The method of claim 26, wherein the channel is designed for chemical communication between at least a first cell in the first well and a second cell in the second well.

28. The method of claim 26, wherein the channel is designed for ion communication between at least a first cell in the first well and a second cell in the second well.

29. The method of claim 22, wherein a well circumference is any one of: a circle and a polygon.

30. The method of claim 21, further comprising:
depositing an adhesion layer on the bottom surface of each well of the plurality of wells.
